(19) United States
(12) Patent Application Publication
(10) Pub. No.: US 2024/0213249 A1
(43) Pub. Date: Jun. 27, 2024

(54) INTEGRATED CIRCUIT DEVICE

(71) Applicant: Samsung Electronics Co., Ltd., Suwon-si (KR)

(72) Inventors: DONGHOON HWANG, Suwon-si (KR); KYUNGHO KIM, Suwon-si (KR); BYUNGHO MOON, Suwon-si (KR); KYUNGHEE CHO, Suwon-si (KR); DOYOUNG CHOI, Suwon-si (KR); INCHAN HWANG, Suwon-si (KR)

(21) Appl. No.: 18/512,094

(22) Filed: Nov. 17, 2023

(30) Foreign Application Priority Data
Dec. 26, 2022 (KR) 10-2022-0185060

(51) Int. Cl. H01L 27/092; H01L 21/822; H01L 21/8238; H01L 23/528; H01L 29/06; H01L 29/417; H01L 29/423; H01L 29/66; H01L 29/775

(52) U.S. Cl. CPC H01L 27/0922; H01L 21/8221; H01L 21/823871; H01L 23/528; H01L 29/0673; H01L 29/41733; H01L 29/42392; H01L 29/66439; H01L 29/775

(57) ABSTRACT

An integrated circuit device includes a lower insulating line extending in a first direction, a plurality of lower channel lines over the lower insulating line, first and second lower gate lines respectively on opposing sides of the lower insulating line and opposing sides of one of the lower channel lines, a third lower gate line extending around upper and lower surfaces of the one of the lower channel line and connecting the first and second lower gate lines to each other, an outer gate line arranged under the lower insulating line and contacting the first and second lower gate lines, an upper insulating line over an upper surface of each lower channel line, a plurality of upper channel lines over the upper insulating line, and an upper gate line extending around one of the upper channel lines.

### CROSS-REFERENCE TO RELATED APPLICATION

This application claims priority under 35 U.S.C. § 119 to Korean Patent Application No. 10-2022-0185060, filed on Dec. 26, 2022, in the Korean Intellectual Property Office, the disclosure of which is incorporated by reference herein in its entirety.

### BACKGROUND

The inventive concept relates to an integrated circuit device, and more particularly, to an integrated circuit device including a multilayer-structured channel line.

Recently, as integrated circuit devices have been rapidly down-scaled, integrated circuit devices with the accuracy of operations as well as high operation speeds may be desirable. In addition, as integrated circuit devices have increasing degrees of integration and decreasing sizes, multilayer structures obtained by stacking integrated circuit devices in a vertical direction may be desirable. In such integrated circuit devices having multilayer structures, structures for reducing the sizes of integrated circuit devices have been developed.

### SUMMARY

The inventive concept provides an integrated circuit device, in which gate contact vias and source/drain contact vias are arranged in a line.

The inventive concept also provides an integrated circuit device, in which a separation distance between gate contact vias decreases.

In addition, the inventive concept is not limited to the aspects described above, and other aspects of the inventive concept may be clearly understood by those of ordinary skill in the art from the following detailed description.

According to an aspect of the inventive concept, there is provided an integrated circuit device including a lower insulating line extending in a first direction, a plurality of lower channel lines over the lower insulating line, a first lower gate line and a second lower gate line, which are respectively arranged on opposing sides of the lower insulating line and opposing sides of one of the plurality of lower channel lines, a third lower gate line extending around (e.g., surrounding) an upper surface and a lower surface of the one of the plurality of lower channel lines and connecting the first lower gate line and the second lower gate line to each other, an outer gate line arranged under the lower insulating line and contacting the first lower gate line and the second lower gate line, an upper insulating line over an upper surface of each of the plurality of lower channel lines, a plurality of upper channel lines arranged over the upper insulating line, and an upper gate line extending around (e.g., surrounding) one of the plurality of upper channel lines.

According to another aspect of the inventive concept, there is provided an integrated circuit device including a lower insulating line, a lower channel line over the lower insulating line, a first lower gate line and a second lower gate line, which are respectively arranged on opposing sides of the lower channel line and opposing sides of the lower insulating line, a third lower gate line extending around (e.g., surrounding) an upper surface and a lower surface of the lower channel line and connecting the first lower gate line and the second lower gate line to each other, a plurality of lower source/drain regions on respective opposing sides of the first lower gate line, the second lower gate line, and the third lower gate line, an outer gate line arranged under the lower insulating line and contacting both the first lower gate line and the second lower gate line, a plurality of lower vias that are respectively connected to the plurality of lower source/drain regions and extend through the lower insulating line, a lower gate contact electrically connected to the outer gate line, an upper insulating line over the upper surface of the lower channel line, a plurality of upper channel lines over the upper insulating line, an upper gate line extending around (e.g., surrounding) one of the plurality of upper channel lines, a plurality of upper source/drain regions on respective sides of the upper gate line in a first direction, a plurality of upper vias respectively and electrically connected to the plurality of upper source/drain regions, and a plurality of upper gate contacts, one of which is electrically connected to the upper gate line.

According to yet another aspect of the inventive concept, there is provided an integrated circuit device including a plurality of lower insulating lines, a lower channel line over the plurality of lower insulating lines, a first lower gate line and a second lower gate line, which are respectively arranged on opposing sides of the lower channel line and one of the plurality of lower insulating lines, a third lower gate line extending around (e.g., surrounding) an upper surface and a lower surface of the lower channel line and connecting the first lower gate line and the second lower gate line to each other, an outer gate line under the plurality of lower insulating lines and contacting both the first lower gate line and the second lower gate line, the outer gate line overlapping the one of the plurality of lower insulating lines in a vertical direction, a lower via electrically connected to the outer gate line, an upper insulating line over the upper surface of the lower channel line, a plurality of upper channel lines over the upper insulating line, an upper gate line extending around (e.g., surrounding) one of the plurality of upper channel lines, and an upper via that is electrically connected to the upper gate line, is spaced apart from the lower via in the vertical direction, and is arranged along a line with a lower via.

### BRIEF DESCRIPTION OF THE DRAWINGS

Example embodiments will be more clearly understood from the following detailed description taken in conjunction with the accompanying drawings in which:

FIG. 1 is a plan view schematically illustrating a layout of an integrated circuit device according to some embodiments of the inventive concept;

FIG. 2 is a bottom view schematically illustrating a layout of an integrated circuit device according to some embodiments of the inventive concept;

FIG. 3 is a cross-sectional view of the integrated circuit device of FIG. 1, taken along a line X-X′ of FIG. 1 according to some embodiments of the inventive concept;

FIG. 4 is a cross-sectional view of the integrated circuit device of FIG. 1, taken along a line Y-Y′ of FIG. 1 according to some embodiments of the inventive concept;

FIG. 5 is an enlarged view of a region V of FIG. 3 according to some embodiments of the inventive concept;

FIG. 6 is an enlarged view of a region VI of FIG. 4 according to some embodiments of the inventive concept;

FIG. 7 is a cross-sectional view illustrating an integrated circuit device according to some embodiments of the inventive concept in correspondence with the cross-section taken along the line Y-Y′ of FIG. 1;

FIG. 8 is a cross-sectional view illustrating an integrated circuit device according to some embodiments of the inventive concept in correspondence with the cross-section taken along the line Y-Y′ of FIG. 1; and

FIGS. 9A, 9B, 9C, 9D, 9E and 9F are schematic cross-sectional views illustrating a method of fabricating an integrated circuit device, according to some embodiments of the inventive concept.

### DETAILED DESCRIPTION

Hereinafter, example embodiments of the inventive concept will be described in detail with reference to the accompanying drawings, and those embodiments may be changed and modified in various ways. However, it should be understood that the inventive concept is not limited to particular embodiments described herein.

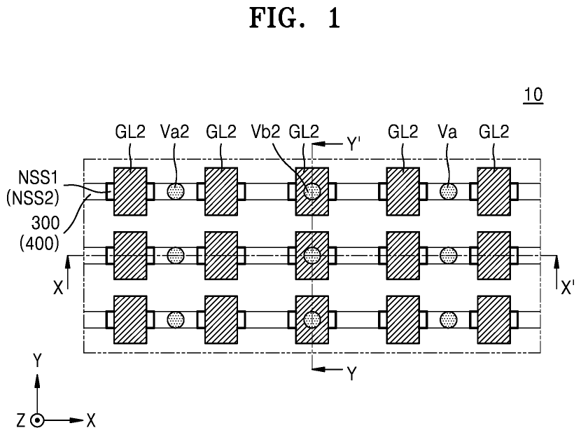

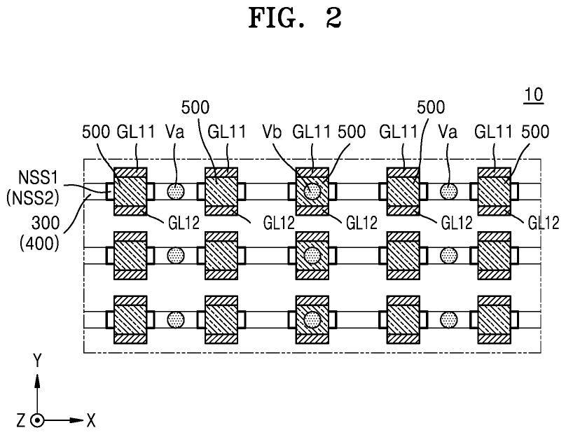

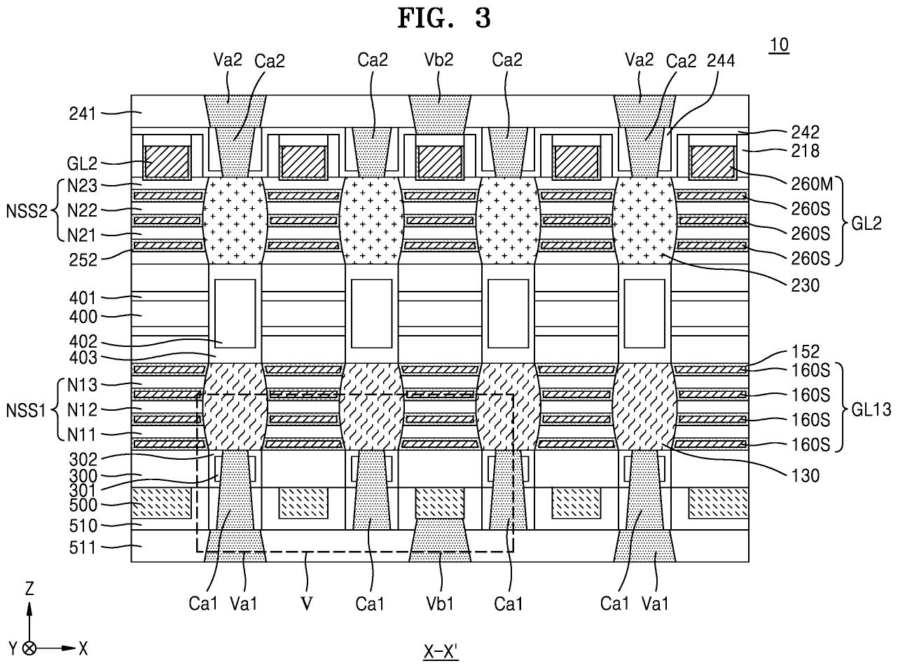

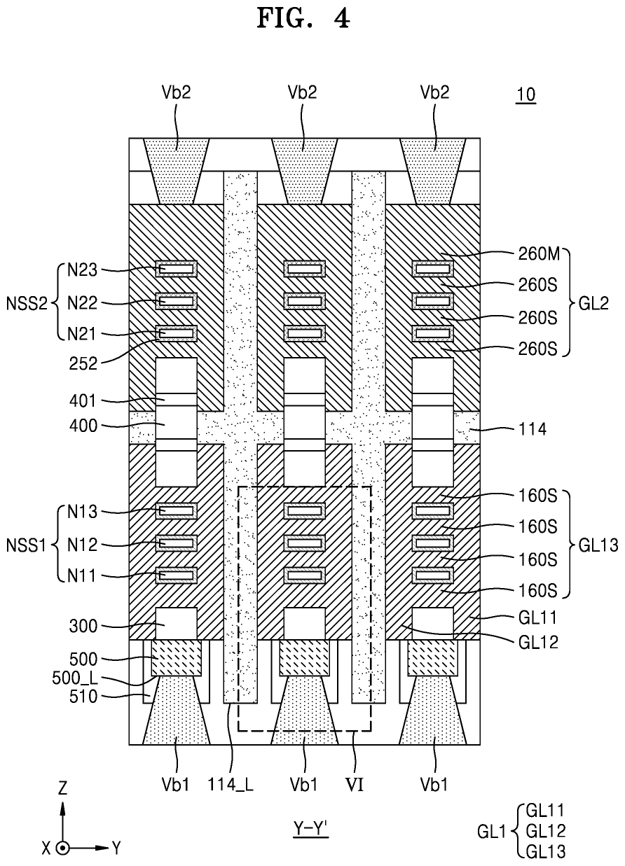

FIG. 1 is a plan view schematically illustrating a layout of an integrated circuit device 10 according to some embodiments of the inventive concept. FIG. 2 is a bottom view schematically illustrating the layout of the integrated circuit device 10 according to some embodiments of the inventive concept. Stated differently, FIG. 1 is a schematic layout of the integrated circuit device 10 viewed from above, and FIG. 2 is a schematic layout of the integrated circuit device 10 viewed from below. FIG. 3 is a cross-sectional view of the integrated circuit device 10, taken along a line X-X′ of FIG. 1 according to some embodiments of the inventive concept. FIG. 4 is a cross-sectional view of the integrated circuit device 10, taken along a line Y-Y′ of FIG. 1 according to some embodiments of the inventive concept.

Referring to FIGS. 1 to 4, the integrated circuit device 10 may include a lower insulating line 300, a lower channel line NSS1, a first lower gate line GL11, a second lower gate line GL12, a third lower gate line GL13, a lower source/drain region 130, an outer gate line 500, an upper insulating line 400, an upper channel line NSS2, an upper gate line GL2, an upper source/drain region 230, and a device isolation layer 114.

Hereinafter, an extension direction of the lower insulating line 300 is a first direction (also referred to as a first horizontal direction), and a direction perpendicular to the first direction is a second direction (also referred to as a second horizontal direction). The first direction is defined to be an X direction, and the second direction is defined to be a Y direction. A direction perpendicular to the first direction and the second direction is defined to be a Z direction (also referred to as a vertical direction).

The lower insulating line 300 of the integrated circuit device 10 may extend in the first direction. The lower channel line NSS1, the upper insulating line 400, and the upper channel line NSS2 may be stacked over the lower insulating line 300. A horizontal width of the lower insulating line 300 in the second direction (that is, the length of the lower insulating line 300 in the Y direction) may be substantially equal to a horizontal width of each of the lower channel line NSS1, the upper insulating line 400, and the upper channel line NSS2 in the second direction. In some embodiments, the lower insulating line 300 may include a plurality of layers. As used herein, “an element A extends in a direction X” (or similar language) may mean that the element A extends longitudinally in the direction X.

In some embodiments, the lower insulating line 300 may further include oxide layers 301. The oxide layers 301 may be spaced apart from each other in the first direction. The oxide layers 301 may be arranged under the lower source/drain region 130. The oxide layers 301 may be used for epitaxial growth of the lower source/drain region 130.

In some embodiments, the lower insulating line 300 may further include insulating films 302. The insulating films 302 may respectively surround the oxide layers 301. That is, the insulating films 302 may be spaced apart from each other in the first direction. The insulating films 302 may suppress the lower source/drain region 130 from receiving signals except for signals of a lower via (that is, Ca1 and Va1).

The lower insulating line 300 may include silicon nitride (SiN), silicon oxide (SiO), SiCN, SiBN, SiON, SiOCN, SiBCN, SiOC, or a combination thereof. As used herein, each of the terms “SiN”, “SiO”, “SiCN”, “SiBN”, “SiON”, “SiOCN”, “SiBCN”, and “SiOC” refers to a material including elements contained in each term and is not a chemical formula representing a stoichiometric relationship.

The integrated circuit device 10 may include a plurality of lower channel lines NSS1. The plurality of lower channel lines NSS1 may be arranged in a line to be spaced apart from each other in the first direction. The plurality of lower channel lines NSS1 may be arranged over the lower insulating line 300. That is, the plurality of lower channel lines NSS1 may be arranged in a line over the lower insulating line 300 to be spaced apart from each other in the first direction. In some embodiments, the plurality of lower channel lines NSS1 may be arranged along the first direction, as illustrated in FIG. 1.

The plurality of lower channel lines NSS1 may each be spaced apart from the lower insulating line 300 with the third lower gate line GL13 therebetween. That is, the third lower gate line GL13 may be arranged on a lower surface of the lower channel line NSS1.

In some embodiments, each of the plurality of lower channel lines NSS1 may include at least one lower nanosheet. A plurality of lower nanosheets N11, N12, and N13 may be spaced apart from each other in a vertical direction (Z direction). In other words, each of the plurality of lower channel lines NSS1 may include the plurality of lower nanosheets N11, N12, and N13 overlapping each other in the vertical direction over the lower insulating line 300. As used herein, “an element A overlapping an element B in a direction X” (or similar language) means that there is at least one line that extends in the direction X and intersects both the elements A and B.

Specifically, the plurality of lower nanosheets N11, N12, and N13 may respectively include a first lower nanosheet N11, a second lower nanosheet N12, and a third lower nanosheet N13, which are stacked in the stated order over the lower insulating line 300. The first lower nanosheet N11, the second lower nanosheet N12, and the third lower nanosheet N13 may be spaced apart from each other in the vertical direction. The third lower gate line GL13 may be arranged between the plurality of lower nanosheets N11, N12, and N13. That is, the plurality of lower nanosheets N11, N12, and N13 and the third lower gate line GL13 may be alternately stacked.

In some embodiments, each of the plurality of lower nanosheets N11, N12, and N13 may have a channel region. For example, each of the plurality of lower nanosheets N11, N12, and N13 may have, but is not limited to, a thickness selected from a range of about 4 nm to about 6 nm. Here, the thickness of each of the plurality of lower nanosheets N11, N12, and N13 refers to a size in the vertical direction (Z direction). In some embodiments, the plurality of lower nanosheets N11, N12, and N13 may have substantially the same thickness in the vertical direction (Z direction). In some embodiments, at least some of the plurality of lower nanosheets N11, N12, and N13 may have different thicknesses from each other in the vertical direction (Z direction).

FIG. 3 illustrates an example in which a planar shape of the lower channel line NSS1 is approximately a quadrangular shape, but the inventive concept is not limited thereto. The lower channel line NSS1 may have various planar shapes depending on respective planar shapes of the lower insulating line 300 and the third lower gate line GL13. Although FIG. 3 illustrates that the plurality of lower channel lines NSS1 are arranged in a line in the first direction (X direction) over one lower insulating line 300, and one lower channel line NSS1 includes the plurality of lower nanosheets N11, N12, and N13. However, the respective numbers of lower nanosheets and lower channel lines NSS1, which are arranged over one lower insulating line 300, are not particularly limited.

In some embodiments, the plurality of lower nanosheets N11, N12, and N13 may respectively include semiconductor layers including the same element. For example, each of the plurality of lower nanosheets N11, N12, and N13 may include an Si layer. In some embodiments, each of the plurality of lower nanosheets N11, N12, and N13 may include an undoped Si layer. In some embodiments, each of the plurality of lower nanosheets N11, N12, and N13 may include an Si layer doped with a dopant of the same conductivity type as a conductivity type of the lower source/drain region 130. In some embodiments, each of the plurality of lower nanosheets N11, N12, and N13 may include an Si layer doped with a dopant of an opposite conductivity type to the conductivity type of the lower source/drain region 130.

The first lower gate line GL11 and the second lower gate line GL12 of the integrated circuit device 10 may be respectively arranged on opposing sides of the plurality of lower channel lines NSS1 in the second direction. That is, the first lower gate line GL11 and the second lower gate line GL12 may be respectively arranged on opposing sides of each of the plurality of lower channel lines NSS1. In addition, the first lower gate line GL11 and the second lower gate line GL12 may be respectively arranged on opposing sides of the lower insulating line 300 in the second direction. In other words, the first lower gate line GL11 and the second lower gate line GL12 may be respectively arranged on opposing sides of the lower insulating line 300 and the lower channel line NSS1 in the second direction, the lower insulating line 300 and the lower channel line NSS1 being stacked in the vertical direction (Z direction).

The first lower gate line GL11 and the second lower gate line GL12 may be spaced apart from each other in the second direction. That is, the first lower gate line GL11 and the second lower gate line GL12 may be spaced apart from each other with the lower channel line NSS1 and the lower insulating line 300 therebetween.

The third lower gate line GL13 of the integrated circuit device 10 may surround an upper surface and a lower surface of the lower channel line NSS1 and may connect the first lower gate line GL11 and the second lower gate line GL12 to each other. The first lower gate line GL11, the second lower gate line GL12, and the third lower gate line GL13 are collectively referred to as a lower gate line GL1.

The third lower gate line GL13 may include a plurality of sub-gate portions 160S. The plurality of sub-gate portions 160S may be respectively arranged one by one between the plurality of lower nanosheets N11, N12, and N13 and between the first lower nanosheet N11 and the lower insulating line 300.

That is, the lower gate line GL1 may surround the lower channel line NSS1. In some embodiments, each of the plurality of lower nanosheets N11, N12, and N13 of the lower channel line NSS1 may be surrounded by the lower gate line GL1.

The lower gate line GL1 may include, for example, a metal, a metal nitride, a metal carbide, or a combination thereof. The metal may be selected from, for example, Ti, W, Ru, Nb, Mo, Hf, Ni, Co, Pt, Yb, Tb, Dy, Er, and Pd. The metal nitride may be selected from, for example, TiN and TaN. The metal carbide may include TiAlC. However, a material constituting the lower gate line GL1 is not limited to the examples set forth above.

A lower gate dielectric film 152 may be arranged between the lower channel line NSS1 and the lower gate line GL1. The lower gate dielectric film 152 may cover a lower surface and a sidewall of a sub-gate portion 160S of the lower gate line GL1.

In some embodiments, the lower gate dielectric film 152 may include a stack structure of an interface film and a high-K film. The interface film may include, for example, a low-K material film having a dielectric constant of about 9 or less, for example, a silicon oxide film, a silicon oxynitride film, or a combination thereof. In some embodiments, the interface film may be omitted. The high-K film may include a material having a dielectric constant that is greater than that of a silicon oxide film. For example, the high-K film may have a dielectric constant of about 10 to about 25. For example, the high-K film may include, but is not limited to, hafnium oxide.

A plurality of nanosheet transistors may be respectively formed in intersection regions between a plurality of lower insulating lines 300 and a plurality of lower gate lines GL1.

A plurality of lower source/drain regions 130 of the integrated circuit device 10 may be arranged on both sides of the first lower gate line GL11, the second lower gate line GL12, and the third lower gate line GL13 in the first direction. In other words, the plurality of lower source/drain regions 130 may be spaced apart from each other in the first direction with the first lower gate line GL11, the second lower gate line GL12, and the third lower gate line GL13 therebetween. That is, the plurality of lower source/drain regions 130 may be arranged in a line along the lower insulating line 300 to be spaced apart from each other in the first direction.

Each of the plurality of lower source/drain regions 130 may have a sidewall facing the plurality of lower nanosheets N11, N12, and N13 of the lower channel line NSS1 that is adjacent thereto. Each of the plurality of lower source/drain regions 130 may be in contact with the plurality of lower nanosheets N11, N12, and N13 of the lower channel line NSS1 that is adjacent thereto.

Each of the plurality of lower source/drain regions 130 may include an epitaxially grown semiconductor layer. In some embodiments, each of the plurality of lower source/drain regions 130 may include a Group IV element semiconductor, a Group IV-IV compound semiconductor, or a combination thereof. In some embodiments, each of the plurality of lower source/drain regions 130 may include an Si layer doped with an n-type dopant, an SiC layer doped with an n-type dopant, or an SiGe layer doped with a p-type dopant. The n-type dopant may be selected from, for example, phosphorus (P), arsenic (As), and antimony (Sb). The p-type dopant may be selected from, for example, boron (B) and gallium (Ga).

The upper insulating line 400 of the integrated circuit device 10 may extend in the first direction. The lower channel line NSS1 and the lower insulating line 300 may be arranged under the upper insulating line 400, and the upper channel line NSS2 may be arranged over the upper insulating line 400. A horizontal width of the upper insulating line 400 in the second direction (that is, the length of the upper insulating line 400 in the Y direction) may be substantially equal to a horizontal width of the upper channel line NSS2 in the second direction.

The upper insulating line 400 may be arranged between the lower channel line NSS1 and the upper channel line NSS2. That is, the upper channel line NSS2 may be arranged over the upper insulating line 400, and the lower channel line NSS1 may be arranged under the upper insulating line 400. The upper insulating line 400 may reduce/prevent a current from flowing between the lower channel line NSS1 and the upper channel line NSS2.

In some embodiments, the upper insulating line 400 may include a plurality of layers. Although FIG. 3 illustrates that the upper insulating line 400 includes three layers, the inventive concept is not limited thereto, and the upper insulating line 400 may include a single layer or include four or more layers. Here, the upper insulating line 400 may further include an insulating layer 401 arranged between the plurality of layers. The insulating layer 401 may include a different material from the upper insulating line 400. The insulating layer 401 may have a different etch rate from the upper insulating line 400.

The upper insulating line 400 may include, for example, silicon nitride (SiN), silicon oxide (SiO), SiCN, SiBN, SiON, SiOCN, SiBCN, SiOC, or a combination thereof.

A plurality of upper channel lines NSS2 of the integrated circuit device 10 may be arranged over the upper insulating line 400. The plurality of upper channel lines NSS2 may be arranged in a line to be spaced apart from each other in the first direction. The upper channel line NSS2 may overlap the upper insulating line 400 in the vertical direction.

In some embodiments, the upper insulating line 400 may include an oxide layer 402 between the upper source/drain region 230 and the lower source/drain region 130. The oxide layer 402 may be used to epitaxially grow the upper source/drain region 230 over the lower source/drain region 130. A process of forming the upper source/drain region 230 by using the oxide layer 402 is described below.

In some embodiments, the upper insulating line 400 may further include an insulating film 403 to reduce or prevent signal transfer between the upper source/drain region 230 and the lower source/drain region 130. The insulating film 403 may surround the oxide layer 402. The insulating film 403 may reduce/prevent a signal from being transferred to the oxide layer 402.

In some embodiments, each of the plurality of upper channel lines NSS2 may include at least one upper nanosheet. A plurality of upper nanosheets N21, N22, and N23 may be spaced apart from each other in the vertical direction (Z direction). In other words, each of the plurality of upper channel lines NSS2 may include the plurality of upper nanosheets N21, N22, and N23 overlapping each other in the vertical direction over the upper insulating line 400.

Specifically, the plurality of upper nanosheets N21, N22, and N23 may respectively include a first upper nanosheet N21, a second upper nanosheet N22, and a third upper nanosheet N23, which are stacked in the stated order over the upper insulating line 400. The first upper nanosheet N21, the second upper nanosheet N22, and the third upper nanosheet N23 may be spaced apart from each other in the vertical direction with the upper gate line GL2 therebetween.

In some embodiments, each of the plurality of upper nanosheets N21, N22, and N23 may have a channel region. For example, each of the plurality of upper nanosheets N21, N22, and N23 may have, but is not limited to, a thickness selected from a range of about 4 nm to about 6 nm. Here, the thickness of each of the plurality of upper nanosheets N21, N22, and N23 refers to a size in the vertical direction (Z direction). In some embodiments, the plurality of upper nanosheets N21, N22, and N23 may have substantially the same thickness in the vertical direction (Z direction). In some embodiments, at least some of the plurality of upper nanosheets N21, N22, and N23 may have different thicknesses from each other in the vertical direction (Z direction).

The upper gate line GL2 of the integrated circuit device 10 may surround the upper channel line NSS2. The upper gate line GL2 may be arranged on the upper insulating line 400 to cover the upper channel line NSS2 and surround each of the plurality of upper nanosheets N21, N22, and N23. Each upper gate line GL2 may include a main gate portion 260M and a plurality of sub-gate portions 260S. The main gate portion 260M may cover an upper surface of the upper channel line NSS2 and extend in the second direction (Y direction). The plurality of sub-gate portions 260S may be integrally connected to the main gate portion 260M and may be respectively arranged one by one between the plurality of upper nanosheets N21, N22, and N23 and between the first upper nanosheet N21 and the upper insulating line 400. The thickness of each of the plurality of sub-gate portions 260S may be less in the vertical direction (Z direction) than the thickness of the main gate portion 260M. In some embodiments, the plurality of sub-gate portions 260S and the main gate portion 260M may form a unitary structure without a visible interface therebetween.

In some embodiments, the integrated circuit device 10 may include a plurality of insulating spacers 218. The plurality of insulating spacers 218 may be arranged on an upper surface of the upper channel line NSS2 to cover both sidewalls of the main gate portion 260M of the upper gate line GL2.

The upper gate line GL2 may include, for example, a metal, a metal nitride, a metal carbide, or a combination thereof. The metal may be selected from, for example, Ti, W, Ru, Nb, Mo, Hf, Ni, Co, Pt, Yb, Tb, Dy, Er, and Pd. The metal nitride may be selected from, for example, TiN and TaN. The metal carbide may include, for example, TiAlC. However, a material constituting the upper gate line GL2 is not limited to the examples set forth above.

An upper gate dielectric film 252 may be arranged between the upper channel line NSS2 and the upper gate line GL2. The upper gate dielectric film 252 may cover a sidewall of the main gate portion 260M of the upper gate line GL2.

In some embodiments, the upper gate dielectric film 252 may include a stack structure of an interface film and a high-K film. The interface film may include a low-K material film having a dielectric constant of about 9 or less, for example, a silicon oxide film, a silicon oxynitride film, or a combination thereof. In some embodiments, the interface film may be omitted. The high-K film may include a material having a dielectric constant that is greater than that of a silicon oxide film. For example, the high-K film may have a dielectric constant of about 10 to about 25. The high-K film may include, but is not limited to, hafnium oxide.

A plurality of upper source/drain regions 230 of the integrated circuit device 10 may be arranged on both sides of the upper gate line GL2 in the first direction. In other words, the plurality of upper source/drain regions 230 may be spaced apart from each other with the upper gate line GL2 therebetween. That is, the plurality of upper source/drain regions 230 may be arranged in a line along the upper insulating line 400 to be spaced apart from each other in the first direction.

Each of the plurality of upper source/drain regions 230 may have a sidewall facing the plurality of upper nanosheets N21, N22, and N23 of the upper channel line NSS2 that is adjacent thereto. Each of the plurality of upper source/drain regions 230 may be in contact with the plurality of upper nanosheets N21, N22, and N23 of the upper channel line NSS2 that is adjacent thereto.

Each of the plurality of upper source/drain regions 230 may include an epitaxially grown semiconductor layer. In some embodiments, each of the plurality of upper source/drain regions 230 may include a Group IV element semiconductor, a Group IV-IV compound semiconductor, or a combination thereof. In some embodiments, each of the plurality of upper source/drain regions 230 may include an Si layer doped with an n-type dopant, an SiC layer doped with an n-type dopant, or an SiGe layer doped with a p-type dopant. The n-type dopant may be selected from, for example, phosphorus (P), arsenic (As), and antimony (Sb). The p-type dopant may be selected from, for example, boron (B) and gallium (Ga).

The outer gate line 500 of the integrated circuit device 10 may be arranged under the lower insulating line 300. That is, the outer gate line 500 may be spaced apart from the lower channel line NSS1 with the lower insulating line 300 therebetween. In other words, the lower channel line NSS1 may be arranged over the lower insulating line 300, and the outer gate line 500 may be arranged under the lower insulating line 300. Accordingly, the lower source/drain region 130 on the lower insulating line 300 may be spaced apart from the outer gate line 500 in the vertical direction. That is, a lower surface of the lower source/drain region 130 may be relatively higher than an upper surface of the outer gate line 500.

The outer gate line 500 may be in contact with the first lower gate line GL11 and the second lower gate line GL12. The outer gate line 500 may be electrically connected to the first lower gate line GL11 and the second lower gate line GL12. Specifically, as illustrated in FIG. 4, the first lower gate line GL11 and the second lower gate line GL12 may be spaced apart from each other in the second direction, and a lower surface of the lower insulating line 300 may be between a lower surface of the first lower gate line GL11 and a lower surface of the second lower gate line GL12. The outer gate line 500 may be in contact with both the lower surface of the first lower gate line GL11 and the lower surface of the second lower gate line GL12.

In some embodiments, the upper surface of the outer gate line 500 may face the lower surface of the lower channel line NSS1 with the lower insulating line 300 therebetween. That is, at least a portion of the outer gate line 500 may overlap the lower channel line NSS1 in the vertical direction. In other words, the outer gate line 500 may overlap, in the vertical direction, a separation space between the first lower gate line GL11 and the second lower gate line GL12. For example, referring to FIGS. 2 and 3, the lower channel line NSS1 and the lower source/drain region 130 may be alternately arranged in the first direction. That is, the lower channel line NSS1 and the lower source/drain region 130 may be arranged in a line in the first direction. Therefore, in a plan view, the outer gate line 500, which overlaps the lower channel line NSS1 in the vertical direction, may be arranged in a line with the lower source/drain region 130 in the first direction.

In some embodiments, the integrated circuit device 10 may further include an insulating layer 510, which surrounds the outer gate line 500. Here, the thickness of a portion of the insulating layer 510, which is formed on a lower surface of the outer gate line 500, may vary depending on the thickness (that is, the length in the Z direction) of the outer gate line 500. A constituent material of the insulating layer 510 may include, for example, silicon nitride (SiN), silicon oxide (SiO), SiCN, SiBN, SiON, SiOCN, SiBCN, SiOC, or a combination thereof.

The outer gate line 500 may include, for example, a metal, a metal nitride, a metal carbide, or a combination thereof. The metal may be selected from, for example, Ti, W, Ru, Nb, Mo, Hf, Ni, Co, Pt, Yb, Tb, Dy, Er, and Pd. The metal nitride may be selected from, for example, TiN and TaN. The metal carbide may include, for example, TiAlC. However, a constituent material of the outer gate line 500 is not limited to the examples set forth above. In some embodiments, the constituent material of the outer gate line 500 may be different from the constituent material of the lower gate line GL1.

In some embodiments, the integrated circuit device 10 may include a plurality of lower insulating lines 300. The plurality of lower insulating lines 300 may extend in the first direction and may be spaced apart from each other in the second direction. That is, the lower insulating lines 300 extending lengthwise in the first direction may be spaced apart from each other in the second direction.

The device isolation layer 114 of the integrated circuit device 10 May be arranged between the plurality of lower insulating lines 300. Therefore, the device isolation layer 114 may be arranged between the plurality of lower gate lines GL1, which respectively surround different lower channel lines NSS1. The device isolation layer 114 may be arranged between a plurality of upper gate lines GL2, which are respectively arranged on different upper channel lines NSS2.

The device isolation layer 114 may include an insulating material. For example, the device isolation layer 114 may include, for example, an oxide film, a nitride film, or a combination thereof. Therefore, the device isolation layer 114 may cause a current not to flow between the lower gate lines GL1 or between the upper gate lines GL2.

A lower surface 114_L of the device isolation layer 114 may be coplanar with a lower surface 510_L of the insulating layer 510. That is, an imaginary plane, in which the lower surface 114_L of the device isolation layer 114 extends, may include the lower surface 510_L of the insulating layer 510. In other words, a vertical level of the lower surface 114_L of the device isolation layer 114 may be substantially equal to a vertical level of the lower surface 510_L of the insulating layer 510. In some embodiments, after the device isolation layer 114 is formed, when a polishing process is performed, the vertical level of the lower surface 114_L of the device isolation layer 114 may be substantially equal to the vertical level of the lower surface 510_L of the insulating layer 510.

In the integrated circuit device 10 according to some embodiments of the inventive concept, a gate contact via may be variously arranged due to the outer gate line 500. In addition, due to the outer gate line 500, the gate contact via may have a height difference from a source/drain contact via that transfers a signal to the lower source/drain region 130, thereby suppressing a short circuit between the gate contact via and the source/drain contact via.

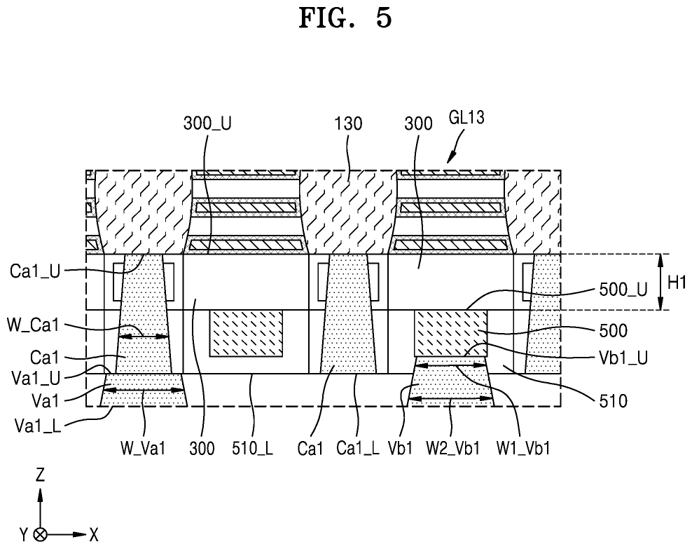

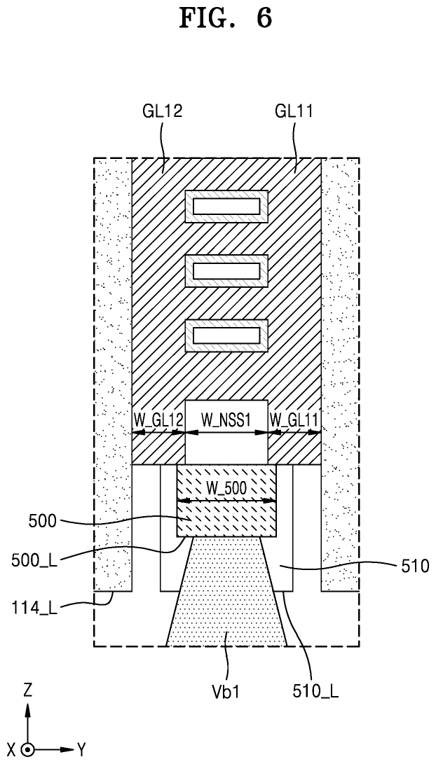

FIG. 5 is an enlarged view of a region V of FIG. 3 according to some embodiments of the inventive concept. FIG. 6 is an enlarged view of a region VI of FIG. 4 according to some embodiments of the inventive concept.

An upper via (that is, Ca2 and Va2), an upper gate contact Vb2, a lower via (that is, Ca1 and Va1), a lower gate contact Vb1, and the outer gate line 500 of the integrated circuit device 10 are described in detail with reference to FIGS. 1 to 6.

The integrated circuit device 10 may include a plurality of lower vias (that is, Ca1 and Va1), a plurality of lower gate contacts Vb1, a plurality of upper vias (that is, Ca2 and Va2), and a plurality of upper gate contacts Vb2.

The plurality of lower vias (that is, Ca1 and Va1) of the integrated circuit device 10 may be respectively connected to a plurality of source/drain regions 130 that are different from each other. Each of the plurality of lower vias (that is, Ca1 and Va1) may be electrically connected to the lower source/drain region 130 through the lower insulating line 300. The lower via (that is, Ca1 and Va1) may transfer a signal to the lower source/drain region 130. In some embodiments, the lower via (that is, Ca1 and Va1) may extend to the inside of the lower source/drain region 130.

In some embodiments, the lower via (that is, Ca1 and Va1) may have a width increasing as a distance from the lower source/drain region 130 increases. That is, the lower via (that is, Ca1 and Va1) may have an inclined side surface. The width of the lower via (that is, Ca1 and Va1) may vary in the vertical direction. For example, the lower via (that is, Ca1 and Va1) may have a horizontal width in the first direction (that is, a length in the X direction) or a horizontal width in the second direction (that is, a length in the Y direction) that increases as a distance from the lower source/drain region 130 increase.

In some embodiments, the lower via (that is, Ca1 and Va1) may include a lower contact via Ca1 and a lower wiring via Va1. The lower contact via Ca1 may be in contact with the lower source/drain region 130. The lower wiring via Va1 may be exposed to the outside of the integrated circuit device 10. The lower contact via Ca1 and the lower wiring via Va1 may be connected to each other and transfer an external signal to the lower source/drain region 130. In some embodiments, the lower contact via Ca1 and the lower wiring via Va1 may include different materials from each other. In addition, the lower contact via Ca1 and the lower wiring via Va1 may include the same material. As used herein, the terms “external/outside device” or “external/outside signal” are intended to broadly refer to a device, circuit, block, module and/or signal that resides externally (i.e., outside of a functional or physical boundary) with respect to a given circuit, block, module, or device.

In some embodiments, the lower wiring via Va1 may be formed through an insulating layer 511. That is, the lower wiring via Va1 may pass through the insulating layer 511 and thus be connected to the lower contact via Ca1. The insulating layer 511 may suppress a short circuit between the lower wiring via Va1 and the lower gate contact Vb1. In addition, the insulating layer 511 may suppress a short circuit between the lower wiring vias Va1.

In some embodiments, the width of the lower contact via Ca1 may be different from the width of the lower wiring via Va1. For example, the area of a lower surface Ca1_L of the lower contact via Ca1 may be less than the area of an upper surface Va1_U of the lower wiring via Va1. The lower contact via Ca1 and the lower wiring via Va1 may be respectively formed by separate processes. Accordingly, a width W_Ca1 of the lower contact via Ca1 may be different from a width W_Va1 of the lower wiring via Va1. In other words, the lower contact via Ca1 and the lower wiring via Va1 may be different from each other in a horizontal width in the first direction (that is, the length in the X direction) or in a horizontal width in the second direction (that is, the length in the Y direction).

In some embodiments, the lower surface Ca1_L of the lower contact via Ca1 may be coplanar with the lower surface 510_L of the insulating layer 510. That is, an imaginary plane, in which the lower surface Ca1_L of the lower contact via Ca1 extends, may include the lower surface 510_L of the insulating layer 510. In other words, a vertical level of the lower surface Ca1_L of the lower contact via Ca1 may be equal to the vertical level of the lower surface 510_L of the insulating layer 510.

In some embodiments, an upper surface Ca1_U of the lower contact via Ca1 may be coplanar with an upper surface 300_U of the lower insulating line 300. That is, a vertical level of the upper surface Ca1_U of the lower contact via Ca1 may be substantially equal to a vertical level of the upper surface 300_U of the lower insulating line 300.

In some embodiments, the upper surface Ca1_U of the lower contact via Ca1 may be spaced apart from an upper surface 500_U of the outer gate line 500 in the vertical direction. That is, the upper surface Ca1_U of the lower contact via Ca1 may be located higher by as much as a first length H1 in the vertical direction than the upper surface 500_U of the outer gate line 500. The lower contact via Ca1 may be formed through the lower insulating line 300, and thus, the first length H1 may be substantially equal to the thickness of the lower insulating line 300.

Each of the plurality of lower gate contacts Vb1 of the integrated circuit device 10 May be connected to the outer gate line 500. The lower gate contact Vb1 may transfer a signal to the outer gate line 500. That is, the lower gate contact Vb1 may be electrically connected to the outer gate line 500 and transfer a signal to the lower gate line GL1.

In some embodiments, the lower gate contact Vb1 may be electrically connected to the outer gate line 500 through the insulating layers 510 and 511. That is, the lower gate contact Vb1 may extend upward from under the outer gate line 500 and be coupled to the outer gate line 500.

In some embodiments, the lower gate contact Vb1 may have a width increasing as a distance from the outer gate line 500 increases. That is, the lower gate contact Vb1 may have an inclined side surface. For example, a horizontal width of an upper surface of the lower gate contact Vb1 in the first direction may be a first width W1_Vb1, and a horizontal width of a lower surface of the lower gate contact Vb1 in the first direction may be a second width W2_V1. The first width W1_Vb1 may be less than the second width W2_V1.

In some embodiments, an upper surface Vb1_U of the lower gate contact Vb1 may be between the upper surface Ca1_U of the lower contact via Ca1 and the lower surface Ca1_L of the lower contact via Ca1. That is, a vertical level of the upper surface Vb1_U of the lower gate contact Vb1 may be higher than the vertical level of the lower surface Ca1_L of the lower contact via Ca1 and lower than the vertical level of the upper surface Ca1_U of the lower contact via Ca1.

In some embodiments, a lower surface Va1_L of the lower wiring via Va1 may be coplanar with the lower surface of the lower gate contact Vb1. That is, an imaginary plane, in which the lower surface Va1_L of the lower wiring via Va1 extends, may include the lower surface of the lower gate contact Vb1.

The plurality of upper vias (that is, Ca2 and Va2) of the integrated circuit device 10 may be respectively connected to the plurality of upper source/drain regions 230 that are different from each other. Each of the plurality of upper vias (that is, Ca2 and Va2) may be electrically connected to the upper source/drain region 230 through an insulating material 244 arranged over the upper source/drain region 230.

In some embodiments, an upper wiring via Va2 may be formed through an insulating layer 241. That is, the upper wiring via Va2 may pass through the insulating layer 241 and thus be connected to an upper contact via Ca2. The insulating layer 241 may suppress a short circuit between the upper wiring via Va2 the upper gate contact Vb2. In addition, the insulating layer 241 may suppress a short circuit between upper wiring vias Va2.

Each of the plurality of upper gate contacts Vb2 of the integrated circuit device 10 May be connected to the upper gate line GL2. The upper gate contact Vb2 may be electrically connected to the upper gate line GL2 and transfer a signal to the upper gate line GL2. In some embodiments, the upper gate contact Vb2 may be in contact with the main gate portion 260M of the upper gate line GL2. Each of the plurality of upper gate contacts Vb2 may be connected to the upper gate line GL2 through an insulating material 242 arranged over the upper gate line GL2.

In some embodiments, the upper gate contact Vb2 may overlap the lower gate contact Vb1 in the vertical direction. Specifically, the upper gate contact Vb2 may be arranged in a line with and may be spaced apart from the lower gate contact Vb1 in the vertical direction (Z direction). That is, the upper gate contact Vb2 may be spaced apart from the lower gate contact Vb1 with the upper gate line GL2, the upper channel line NSS2, the upper insulating line 400, the lower channel line NSS1, the lower insulating line 300, and the outer gate line 500 therebetween.

The outer gate line 500 of the integrated circuit device 10 according to some embodiments of the inventive concept may connect the first lower gate line GL11 with the second lower gate line GL12, and the lower gate contact Vb1 connected to the outer gate line 500 may be arranged in a line with the upper gate contact Vb2 in the vertical direction.

The plurality of lower vias (that is, Ca1 and Va1) and the plurality of upper vias (that is, Ca2 and Va2) may each be referred to as a source/drain contact via, and the plurality of lower gate contacts Vb1 and the plurality of upper gate contacts Vb2 may each be referred to as a gate contact via.

Each of the source/drain contact via and the gate contact via may include, for example, a metal, a conductive metal nitride, or a combination thereof. For example, each of the source/drain contact via and the gate contact via may include W, Cu, Al, Ti, Ta, TiN, TaN, an alloy thereof, or a combination thereof.

A second-direction horizontal width (i.e., a horizontal width in the second direction) of the outer gate line 500 of the integrated circuit device 10 May be greater than a second-direction horizontal width (i.e., a horizontal width in the second direction) of the lower channel line NSS1. When the second-direction horizontal width of the outer gate line 500 is a first distance W_500 and the second-direction horizontal width of the lower channel line NSS1 is a second distance W_NSS1, the first distance W_500 may be greater than the second distance W_NSS1.

A separation distance between the first lower gate line GL11 and the second lower gate line GL12 may be substantially equal to the second-direction horizontal width of the lower channel line NSS1, that is, the second distance W_NSS1. The first distance W_500 may be greater than the second distance W_NSS1, and thus, at least a portion of the outer gate line 500 may be in contact with the first lower gate line GL11 and the second lower gate line GL12.

In some embodiments, the first distance W_500 may be greater than the second distance W_NSS1 by as much as about 5 nm to about 10 nm. That is, an overlapping length of the outer gate line 500 with the first lower gate line GL11 and the second lower gate line GL12 in the second direction may be about 5 nm to about 10 nm.

A second-direction horizontal width (i.e., a horizontal width in the second direction) of the first lower gate line GL11 may be a third distance W_GL11, and a second-direction horizontal width (i.e., a horizontal width in the second direction) of the second lower gate line GL12 may be a fourth distance W_GL12. Here, the first distance W_500 may be less than a sum of the second distance W_NSS1, the third distance W_GL11, and the fourth distance W_GL12. That is, both side portions of the outer gate line 500 may be respectively arranged under the first lower gate line GL11 and the second lower gate line GL12. In other words, the outer gate line 500 may not be out of respective outer sides of the first lower gate line GL11 and the second lower gate line GL12.

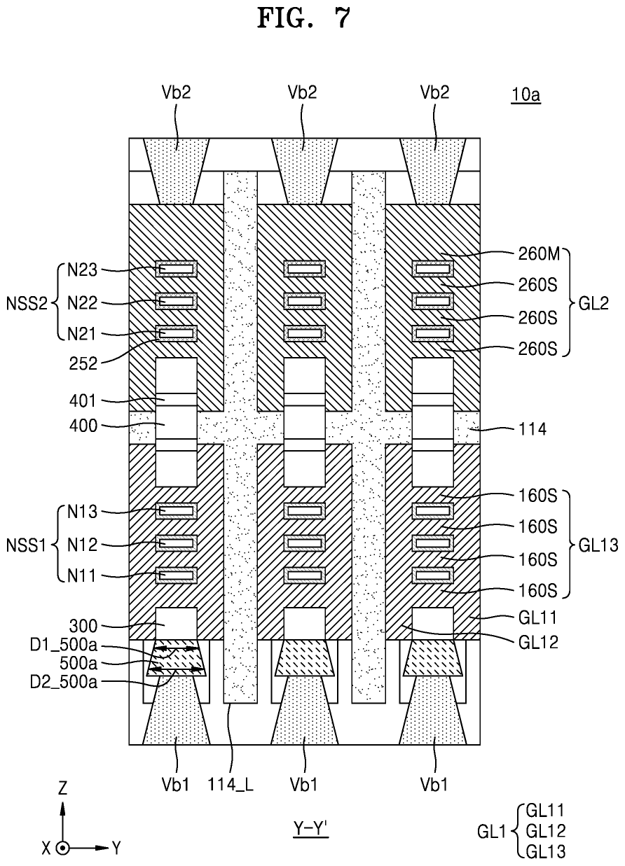

FIG. 7 is a cross-sectional view illustrating an integrated circuit device 10a according to some embodiments of the inventive concept in correspondence with the cross-section taken along the line Y-Y′ of FIG. 1.

Referring to FIG. 7, the integrated circuit device 10a may include the lower insulating line 300, the lower channel line NSS1, the lower gate line GL1, an outer gate line 500a, the upper insulating line 400, the upper channel line NSS2, the upper gate line GL2, and the device isolation layer 114.

Hereinafter, repeated descriptions between the integrated circuit device 10a of FIG. 7 and the integrated circuit device 10 of FIG. 4 are omitted, and differences therebetween are described. The outer gate line 500a of the integrated circuit device 10a may have a width increasing as a distance from the lower insulating line 300 increases. In other words, the outer gate line 500a may have a first-direction horizontal width or a second-direction horizontal width, which increases as a distance from the lower insulating line 300 increases.

In some embodiments, the second-direction horizontal width of an upper surface of the outer gate line 500a may be a third width D1_500a. The second-direction horizontal width of a lower surface of the outer gate line 500a may be a fourth width D2_500a. The third width D1_500a may be less than the fourth width D2_500a. That is, the area of the upper surface of the outer gate line 500a may be smaller than the area of the lower surface of the outer gate line 500a. In other words, the outer gate line 500a may have an inclined side surface.

In general integrated circuit devices, a gate contact via for transferring a signal to the lower gate line GL1 is arranged on the first lower gate line GL11 or the second lower gate line GL12 of the lower gate line GL1. In the integrated circuit device 10a according to some embodiments of the inventive concept, a gate contact via may be variously arranged due to the outer gate line 500a. In addition, due to the outer gate line 500a, the gate contact via may have a height difference from a source/drain contact via that transfers a signal to the lower source/drain region 130, thereby suppressing a short circuit between the gate contact via and the source/drain contact via.

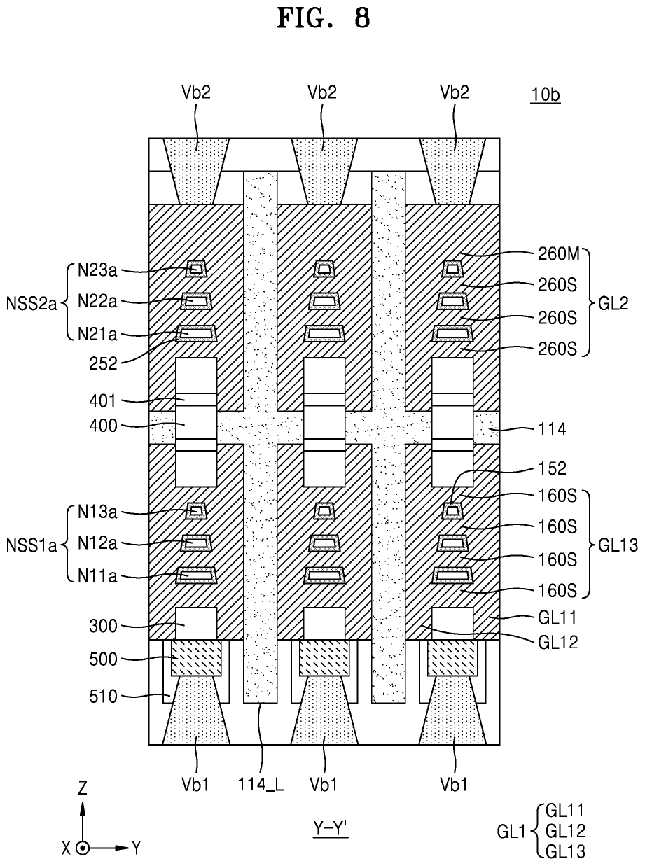

FIG. 8 is a cross-sectional view illustrating an integrated circuit device 10b according to some embodiments of the inventive concept in correspondence with the cross-section taken along the line Y-Y′ of FIG. 1.

Referring to FIG. 8, the integrated circuit device 10b may include the lower insulating line 300, a lower channel line NSS1a, the lower gate line GL1, the outer gate line 500, the upper insulating line 400, an upper channel line NSS2a, the upper gate line GL2, and the device isolation layer 114.

Hereinafter, repeated descriptions between the integrated circuit device 10b of FIG. 8 and the integrated circuit device 10 of FIG. 4 are omitted, and differences therebetween are described.

The lower channel line NSS1a of the integrated circuit device 10b may have a width decreasing as a distance from the lower insulating line 300 increases. That is, the area of a lower surface of the lower channel line NSS1a may be greater than the area of an upper surface of the lower channel line NSS1a.

In some embodiments, the lower channel line NSS1a may include a plurality of lower nanosheets N11a, N12a, and N13a. The lower channel line NSS1a may include a first lower nanosheet N11a, a second lower nanosheet N12a, and a third lower nanosheet N13a, which are stacked in the stated order.

At least some of the plurality of lower nanosheets N11a, N12a, and N13a may have different sizes from each other in the first direction (X direction) and/or the second direction (Y direction). For example, as shown in FIG. 8, the plurality of lower nanosheets N11a, N12a, and N13a may have different widths from each other in the second direction (Y direction) and may each have a width in the second direction (Y direction) increasing as a distance from the lower insulating line 300 decreases. Among the plurality of lower nanosheets N11a, N12a, and N13a, a horizontal width of the first lower nanosheet N11a, which is closest to the lower insulating line 300, in the second direction (Y direction) may be greater than a horizontal width of the third lower nanosheet N13a, which is farthest from the lower insulating line 300, in the second direction (Y direction).

In some embodiments, the first lower nanosheet N11a may have a horizontal width in the second direction decreasing as a distance from the lower insulating line 300 increases. This may be the same for the second lower nanosheet N12a and the third lower nanosheet N13a.

The upper channel line NSS2a of the integrated circuit device 10b may have a width decreasing as a distance from the upper insulating line 400 increases. That is, the area of a lower surface of the upper channel line NSS2a may be greater than the area of an upper surface of the upper channel line NSS2a.

In some embodiments, the upper channel line NSS2a may include a plurality of upper nanosheets N21a, N22a, and N23a. The upper channel line NSS2a may include a first upper nanosheet N21a, a second upper nanosheet N22a, and a third upper nanosheet N23a, which are stacked in the stated order.

At least some of the plurality of upper nanosheets N21a, N22a, and N23a may have different sizes from each other in the first direction (X direction) and/or the second direction (Y direction). For example, as shown in FIG. 8, the plurality of upper nanosheets N21a, N22a, and N23a may have different widths from each other in the second direction (Y direction) and may each have a width in the second direction (Y direction) increasing as a distance from the upper insulating line 400 decreases. Among the plurality of upper nanosheets N21a, N22a, and N23a, a horizontal width of the first upper nanosheet N21a, which is closest to the upper insulating line 400, in the second direction (Y direction) may be greater than a horizontal width of the third upper nanosheet N23a, which is farthest from the upper insulating line 400, in the second direction (Y direction).

In some embodiments, the first upper nanosheet N21a may have a horizontal width decreasing as a distance from the upper insulating line 400 increases. This may be the same for the second upper nanosheet N22a and the third upper nanosheet N23a.

In general integrated circuit devices, a gate contact via for transferring a signal to the lower gate line GL1 is arranged on the first lower gate line GL11 or the second lower gate line GL12 of the lower gate line GL1. In the integrated circuit device 10b according to some embodiments of the inventive concept, a gate contact via may be variously arranged due to the outer gate line 500. In addition, due to the outer gate line 500, the gate contact via may have a height difference from a source/drain contact via that transfers a signal to the lower source/drain region 130, thereby suppressing a short circuit between the gate contact via and the source/drain contact via.

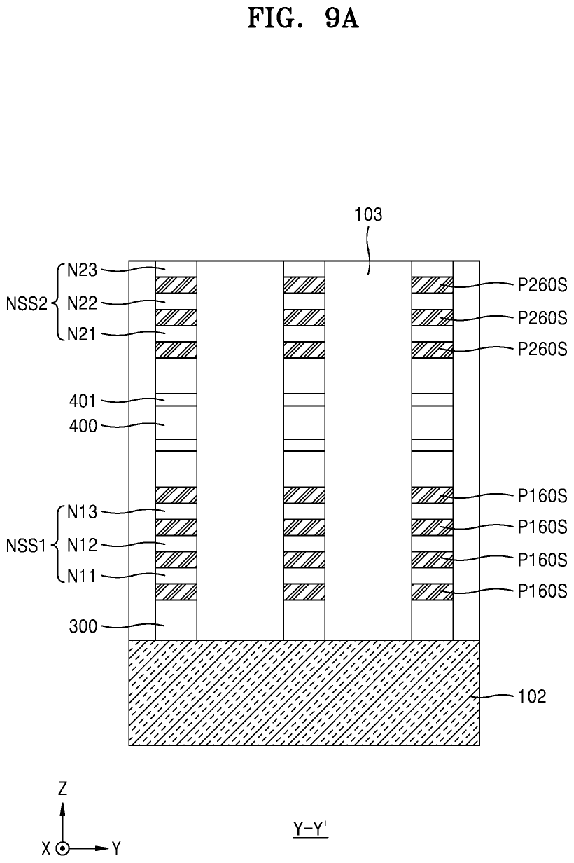

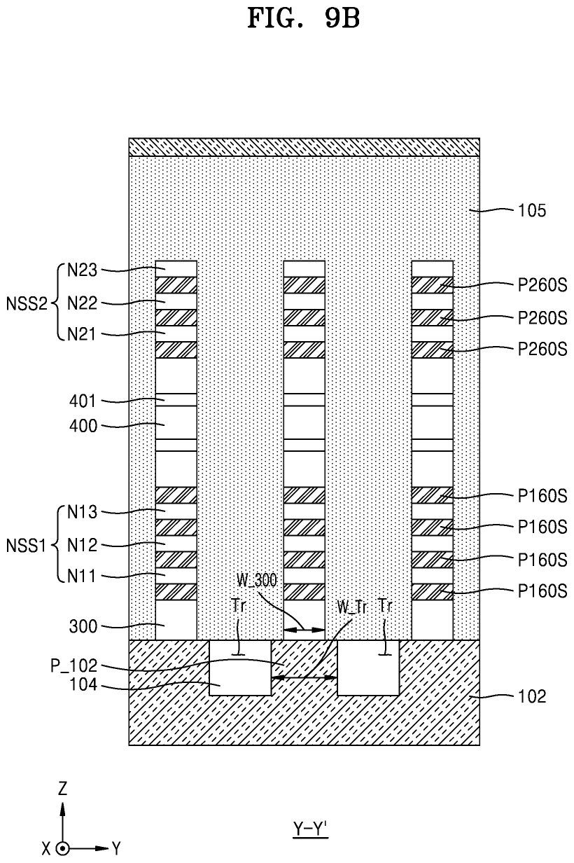

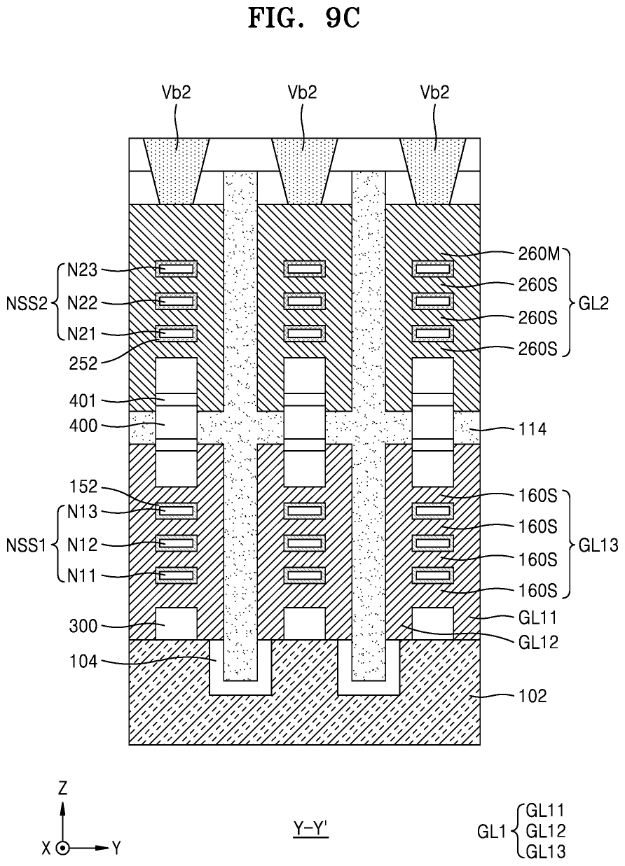

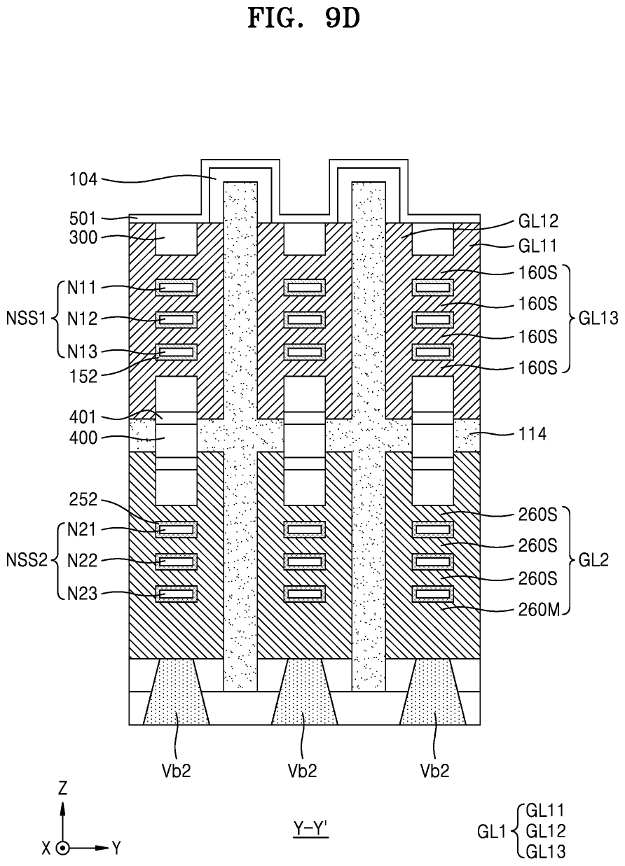

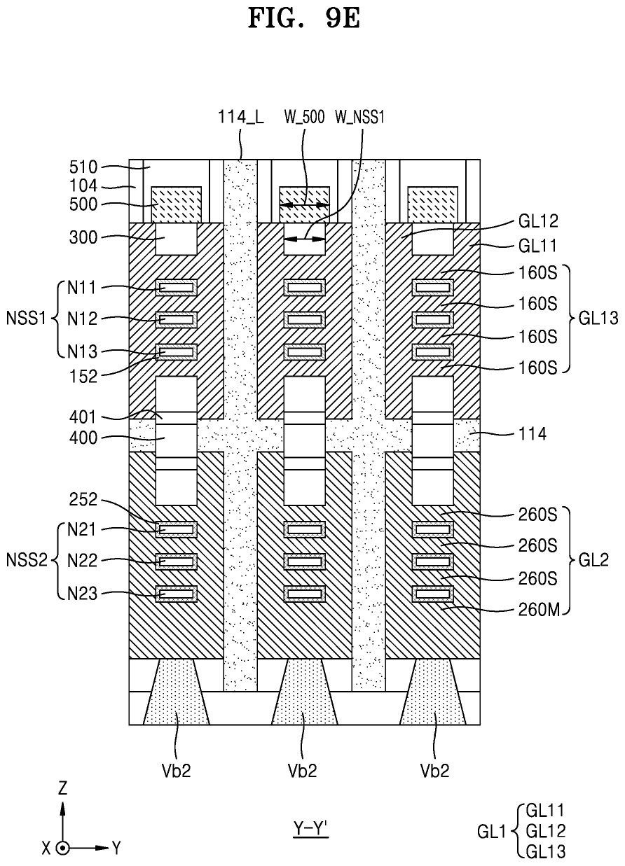

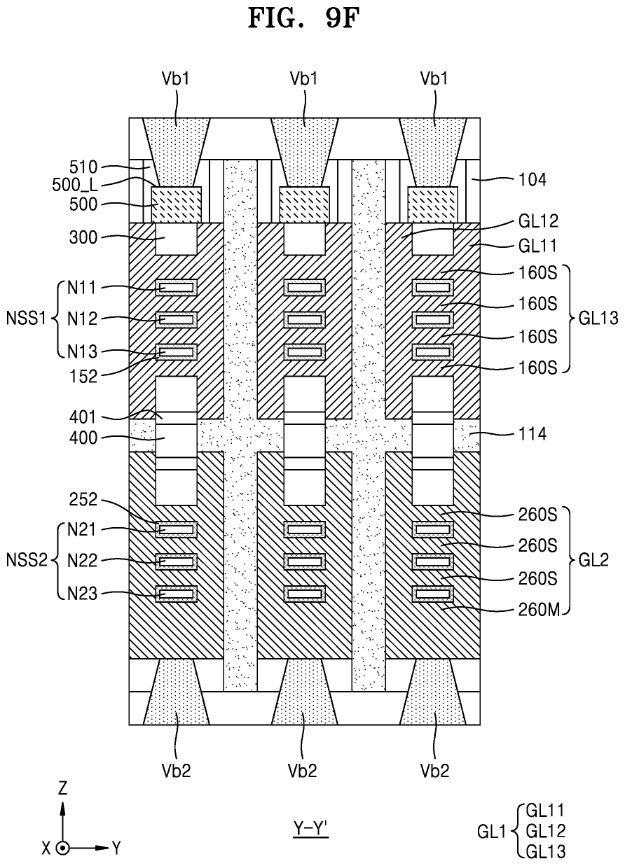

FIGS. 9A to 9F are schematic cross-sectional views illustrating a method of fabricating an integrated circuit device, according to some embodiments of the inventive concept. Specifically, FIGS. 9A to 9F respectively illustrate cross-sectional views of the integrated circuit device in correspondence with the cross-section taken along the line Y-Y′ of FIG. 1. In some embodiments, processes may be performed sequentially as illustrated in FIGS. 9A through 9F.

Referring to FIG. 9A, a plurality of lower insulating lines, a plurality of lower channel lines, a plurality of upper insulating lines, and a plurality of upper channel lines may be arranged on a substrate 102.

The substrate 102 may include, for example, a wafer including silicon (Si). In some embodiments, the substrate 102 may include a wafer including a semiconductor element, such as germanium (Ge), or a compound semiconductor, such as silicon carbide (SiC), gallium arsenide (GaAs), indium arsenide (InAs), or indium phosphide (InP). In some embodiments, the substrate 102 may have a silicon-on-insulator (SOI) structure.

The plurality of lower insulating lines 300 may be spaced apart from each other in the second direction. The lower channel line NSS1, the upper insulating line 400, and the upper channel line NSS2 may be stacked in the stated order over the lower insulating line 300.

In some embodiments, a silicon nitride layer for a lower insulating line is stacked on the substrate 102, and then, silicon germanium (SiGe) and silicon (Si), for a lower channel line, are alternately stacked. Next, a silicon nitride layer for an upper insulating line is stacked, and then, silicon germanium (SiGe) and silicon (Si), for an upper channel line, are alternately stacked.

Next, the plurality of lower insulating lines 300, the plurality of lower channel lines NSS1, the plurality of upper insulating lines 400, and the plurality of upper channel lines NSS2 may be formed by an etching process. Next, through an oxidation process, a silicon oxide layer 103 may be grown in a space obtained by the etching process. Here, the upper insulating line may include a plurality of layers.

Referring to FIG. 9B, the silicon oxide layer 103 (see FIG. 9A) and at least a portion of the substrate 102 may be etched by an etching process, thereby forming a plurality of trenches in an upper surface of the substrate 102. A plurality of first trenches Tr may be arranged on both sides of the lower insulating line 300.

When a separation distance between the plurality of first trenches Tr in the second direction is a third distance W_Tr, and the horizontal width of the lower insulating line 300 in the second direction is a fourth distance W_300, the third distance W_Tr may be greater than the fourth distance W_300.

Through a process of forming the plurality of first trenches Tr, a protrusion P_102, which has a second-direction width of the third distance W_Tr, may be formed under the lower insulating line 300 on the substrate 102. Afterwards, the outer gate line 500 (see FIG. 9E) may be formed in at least a portion of the protrusion P_102.

Next, a silicon oxide layer 104 may be grown in a first trench Tr by an oxidation process, and a dummy gate line 105 for forming the upper gate line GL2 (see FIG. 9C) and the lower gate line GL1 (see FIG. 9C) may be formed.

Referring to FIG. 9C, the lower gate line GL1, the upper gate line GL2, and the device isolation layer 114 may be formed on both sides of the lower insulating line 300, the lower channel line NSS1, the upper insulating line 400, and the upper channel line NSS2.

In some embodiments, a preliminary first lower gate line and a preliminary second lower gate line, which are apart from each other in the second direction with the lower insulating line 300 therebetween, may be formed, followed by forming the lower source/drain region 130 (see FIG. 3) by epitaxial growth, and then, the dummy gate line 105 may be removed. The first lower gate line GL11 and the second lower gate line GL12 may be formed by filling a space, from which the dummy gate line 105 is removed, with a metal.

Here, a preliminary third lower gate line P160S (see FIG. 9B) between nanosheets (that is, N11, N12, and N13) of the lower channel line NSS1 may also be removed, and a metal may fill a space from which the preliminary third lower gate line P160S (see FIG. 9B) is removed, thereby forming the third lower gate line GL13. In this manner, the lower gate line GL1 may be formed. In addition, the upper gate line GL2 may be formed by repeating the process described above.

After the lower gate line GL1 and the upper gate line GL2 are formed, a second trench may be formed by an etching process to extend to the substrate 102 through the upper gate line GL2 and the lower gate line GL1, and the device isolation layer 114 may be formed in the second trench.

Although not shown in FIGS. 9A to 9F, operations of fabricating the lower source/drain region 130 (see FIG. 3) and the upper source/drain region 230 (see FIG. 3) are described. A plurality of recesses may be formed in at least a portion of the lower insulating line 300 to be spaced apart from each other in the first direction, and the plurality of lower source/drain regions 130 (see FIG. 3) may be respectively formed in the plurality of recesses by epitaxial growth. After the lower source/drain region 130 (see FIG. 3) is formed, a silicon oxide layer is grown on the lower source/drain region 130 (see FIG. 3). The plurality of upper source/drain regions 230 (see FIG. 3) may be formed on the silicon oxide layer by epitaxial growth.

Next, the upper gate contact Vb2 may be formed to be connected to the upper gate line GL2. Specifically, a third trench may be formed by etching at least a portion of the upper gate line GL2. The upper gate contact Vb2 may be formed by filling the third trench with a metal. Depending on etching methods, the third trench may have an inclined side surface. That is, the upper gate contact Vb2 may have a width increasing as a distance from the upper gate line GL2 increases.

Referring to FIG. 9D, an operation of removing the substrate 102 is illustrated.

Specifically, flipping may be performed such that the lower insulating line 300 is above the upper insulating line 400. That is, the substrate 102 (see FIG. 9C) may be located at the uppermost position through flipping. The substrate 102 may be removed by polishing and wet etching.

After the substrate 102 (see FIG. 9C) is removed, the first lower gate line GL11, the second lower gate line GL12, the lower insulating line 300, and the silicon oxide layer 104 that covers the device isolation layer 114 may be exposed to the outside. Next, a silicon nitride layer 501 may be formed, thereby protecting the device isolation layer 114, the lower insulating line 300, the first lower gate line GL11, the second lower gate line GL12, and the silicon oxide layer 104.

Referring to FIG. 9E, an operation of forming the outer gate line 500 is illustrated.

Specifically, in a resulting product of FIG. 9D, the outer gate line 500 may be formed in at least a portion of the space from which the substrate 102 is removed. For example, the outer gate line 500 may be formed between a plurality of device isolation layers 114. That is, the outer gate line 500 may be formed to contact the silicon oxide layer 104, which surrounds a side surface of the device isolation layer 114.

In other words, the outer gate line 500 may be formed on the lower insulating line 300, the first lower gate line GL11, and the second lower gate line GL12. A second-direction width (that is, W_500) of the outer gate line 500 may be greater than a second-direction width (that is, W_NSS1) of the lower channel line NSS1. That is, the outer gate line 500 may be in contact with the first lower gate line GL11 and the second lower gate line GL12.

Next, the insulating layer 510 may be formed on the outer gate line 500 and the device isolation layer 114. A polishing process (for example, a breakthrough (BT) etch process or a chemical mechanical polishing (CMP) process) may be performed such that the device isolation layer 114 is exposed to the outside. That is, the vertical level of the lower surface 114_L of the device isolation layer 114 may be equal to the vertical level of the lower surface 510_L of the insulating layer 510. In other words, the lower surface 114_L of the device isolation layer 114 may be coplanar with the lower surface 510_L of the insulating layer 510.

Referring to FIG. 9F, the lower gate contact Vb1 may be formed to be connected to the outer gate line 500.

Specifically, a fourth trench may be formed by etching the insulating layer 510. The lower gate contact Vb1 may be formed by filling the fourth trench with a metal. Although not shown in FIG. 9F, the lower wiring via Va1 may be formed together with the lower gate contact Vb1. The lower wiring via Va1 and the lower gate contact Vb1 may be arranged in a line to be spaced apart from each other in the first direction.

In the process of fabricating the integrated circuit device 10 according to some embodiments of the inventive concept, the outer gate line 500 may be formed through a process of forming the first trench Tr (see FIG. 9B). Due to the outer gate line 500, a position of the lower gate line GL1 may be identified, and thus, the lower gate contact Vb1 may be aligned with the lower gate line GL1. Therefore, the lower gate contact Vb1 and the lower channel line NSS1 may be formed in a line.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure.

As used herein, an element or region that is “covering” or “surrounding” or “filling” another element or region may completely or partially cover or surround or fill the other element or region. Further, “an element A connected to an element B” (or similar language) may mean that the element A is electrically connected to the element B and/or the element A contacts the element B.

While the inventive concept has been particularly shown and described with reference to some example embodiments thereof, it will be understood that various changes in form and details may be made therein without departing from the scope of the following claims. Accordingly, the above-disclosed subject matter is to be considered illustrative, and not restrictive, and the appended claims are intended to cover all such modifications, enhancements, and other embodiments, which fall within the scope of the inventive concept. Thus, to the maximum extent allowed by law, the scope is to be determined by the broadest permissible interpretation of the following claims and their equivalents and shall not be restricted or limited by the foregoing detailed description.

What is claimed is:

1. An integrated circuit device comprising:
a lower insulating line extending in a first direction;
a plurality of lower channel lines over the lower insulating line;
a first lower gate line and a second lower gate line, which are respectively on opposing sides of the lower insulating line and opposing sides of one of the plurality of lower channel lines;
a third lower gate line extending around an upper surface and a lower surface of the one of the plurality of lower channel lines and connecting the first lower gate line and the second lower gate line to each other;
an outer gate line under the lower insulating line and contacting both the first lower gate line and the second lower gate line;
an upper insulating line over the plurality of lower channel lines;
a plurality of upper channel lines over the upper insulating line; and
an upper gate line extending around one of the plurality of upper channel lines.

2. The integrated circuit device of claim 1, wherein the plurality of lower channel lines are arranged along the first direction and are spaced apart from each other, and
the first lower gate line and the second lower gate line are spaced apart from each other in a second direction that is perpendicular to the first direction.

3. The integrated circuit device of claim 2, wherein each of the plurality of lower channel lines comprises at least one lower nanosheet, and
each of the plurality of upper channel lines comprises at least one upper nanosheet.

4. The integrated circuit device of claim 3, wherein the at least one lower nanosheet has a width decreasing as a distance from the lower insulating line increases, and
the at least one upper nanosheet has a width decreasing as a distance from the upper insulating line increases.

5. The integrated circuit device of claim 2, wherein a width of each of the plurality of lower channel lines in the second direction is less than a width of the outer gate line in the second direction.

6. The integrated circuit device of claim 5, wherein the width of the outer gate line in the second direction is greater than the width of each of the plurality of lower channel lines in the second direction by about 5 nm to about 10 nm.

7. The integrated circuit device of claim 2, wherein a sum of a width of the first lower gate line in the second direction, a width of each of the plurality of lower channel lines in the second direction, and a width of the second lower gate line in the second direction is greater than a width of the outer gate line in the second direction.

8. The integrated circuit device of claim 1, wherein an upper surface of the outer gate line faces a lower surface of the one of the plurality of lower channel lines, and the lower insulating line is between the upper surface of the outer gate line and the lower surface of the one of the plurality of lower channel lines.

9. The integrated circuit device of claim 1, wherein at least a portion of the outer gate line overlaps the lower insulating line in a vertical direction that is perpendicular to the first direction.

10. The integrated circuit device of claim 1, wherein the outer gate line has a width increasing as a distance from the lower insulating line increases.

11. The integrated circuit device of claim 1, further comprising:
a plurality of lower source/drain regions on respective opposing sides of the first lower gate line, the second lower gate line, and the third lower gate line; and
a plurality of upper source/drain regions on respective opposing sides of the upper gate line,
wherein the plurality of lower source/drain regions are on the lower insulating line.

12. The integrated circuit device of claim 11, further comprising:
a plurality of lower contact vias that are respectively connected to the plurality of lower source/drain regions and extend through the lower insulating line; and
an insulating layer extending around the outer gate line,
wherein lower surfaces of the plurality of lower contact vias are coplanar with a lower surface of the insulating layer.

13. An integrated circuit device comprising:
a lower insulating line;
a lower channel line over the lower insulating line;
a first lower gate line and a second lower gate line, which are respectively on opposing sides of the lower channel line and opposing sides of the lower insulating line;
a third lower gate line extending around an upper surface and a lower surface of the lower channel line and connecting the first lower gate line and the second lower gate line to each other;
a plurality of lower source/drain regions on respective opposing sides of the first lower gate line, the second lower gate line, and the third lower gate line;
an outer gate line under the lower insulating line and contacting both the first lower gate line and the second lower gate line;
a plurality of lower vias that are respectively connected to the plurality of lower source/drain regions and extend through the lower insulating line;
a lower gate contact electrically connected to the outer gate line;
an upper insulating line over the upper surface of the lower channel line;
a plurality of upper channel lines over the upper insulating line;
an upper gate line extending around one of the plurality of upper channel lines;
a plurality of upper source/drain regions on respective sides of the upper gate line;
a plurality of upper vias electrically connected to the plurality of upper source/drain regions, respectively; and
a plurality of upper gate contacts, one of which is electrically connected to the upper gate line.

14. The integrated circuit device of claim 13, wherein each of the plurality of lower vias comprises a lower contact via and a lower wiring via, and
a width of the lower contact via is different from a width of the lower wiring via.

15. The integrated circuit device of claim 13, further comprising an insulating layer extending around the outer gate line,
wherein the lower gate contact extends through the insulating layer and is electrically connected to the outer gate line.

16. The integrated circuit device of claim 13, wherein each of the plurality of lower vias has a width increasing as a distance from a respective one of the plurality of lower source/drain regions increases, and
the lower gate contact has a width increasing a distance from the outer gate line increases.

17. The integrated circuit device of claim 13, wherein the lower gate contact and one of the plurality of upper gate contacts are arranged along a line and spaced apart from each other in a vertical direction.

18. An integrated circuit device comprising:
a plurality of lower insulating lines;
a lower channel line over the plurality of lower insulating lines;
a first lower gate line and a second lower gate line, which are respectively on opposing sides of the lower channel line and one of the plurality of lower insulating lines;
a third lower gate line extending around an upper surface and a lower surface of the lower channel line and connecting the first lower gate line and the second lower gate line to each other;
an outer gate line under the plurality of lower insulating lines and contacting both the first lower gate line and the second lower gate line, the outer gate line overlapping the one of the plurality of lower insulating lines in a vertical direction;
a lower via electrically connected to the outer gate line;
an upper insulating line over the upper surface of the lower channel line;
a plurality of upper channel lines over the upper insulating line;
an upper gate line extending around one of the plurality of upper channel lines; and
an upper via that is electrically connected to the upper gate line, is spaced apart from the lower via in the vertical direction, and is arranged along a line with the lower via.

19. The integrated circuit device of claim 18, wherein the plurality of lower insulating lines, which extend in a first direction, are spaced apart from each other in a second direction that is perpendicular to the first direction, and
the integrated circuit device further comprises a device isolation layer between the plurality of lower insulating lines.

20. The integrated circuit device of claim 19, further comprising an insulating layer extending around the outer gate line,
wherein a lower surface of the device isolation layer is coplanar with a lower surface of the insulating layer.
